(19) United States
(12) Patent Application Publication
(10) Pub. No.: US 2017/0115363 A1
(43) Pub. Date: Apr. 27, 2017

(54) Magnetic Field Sensor With Three-Dimensional Spiral Reset Coil

(71) Applicant: Memsic Semiconductor (Wuxi) Co., Ltd., Wuxi (CN)

(72) Inventors: Leyue Jiang, Wuxi (CN); Yang Zhao, Andover, MA (US)

(21) Appl. No.: 15/333,178

(22) Filed: Oct. 24, 2016

Related U.S. Application Data
(63) Continuation-in-part of application No. 15/299,283, filed on Oct. 20, 2016.

(30) Foreign Application Priority Data
Oct. 26, 2015 (CN) 201510700943.X
Nov. 10, 2015 (CN) 201510759597.2

(51) Int. Cl. G01R 33/09; G01R 33/00; G01R 35/00

(52) U.S. Cl. CPC G01R 33/091; G01R 35/00; G01R 33/0005

(57) ABSTRACT

A magnetic field sensor with at least one three-dimensional spiral reset coil, as well as a method of making the same, are provided. The magnetic field sensor comprises at least one sensing unit having a magnetic easy axis and a magneto-sensitive axis perpendicular to the magnetic easy axis, and at least one three-dimensional spiral reset coil spirally surrounding a corresponding sensing unit of the at least one sensing unit. The spiral reset coil comprises a first wire portion disposed on two opposite sides of the corresponding sensing unit, and a third wire portion coupling the first and second wire portions. Compared with a conventional planer reset coil, the three-dimensional spiral reset coil provides a stronger magnetic field under same current. Therefore, a substrate area for fabricating the magnetic field sensors may be utilized more effectively.

### CROSS-REFERENCE TO RELATED APPLICATIONS

The present disclosure is a continuation-in-part (CIP) of U.S. patent application Ser. No. 15/299,283, filed on 20 Oct. 2016, and also claims the priority benefit of Chinese Patent Application No. 201510700943.X, filed on 26 Oct. 2015, as well as Chinese Patent Application No. 201510759597.2, filed on 10 Nov. 2015. Each of the two Chinese patent applications is incorporated by reference in its entirety.

### TECHNICAL FIELD

The present disclosure relates to a magnetic field sensor, and in particular, to a magnetic field sensor with at least one three-dimensional spiral reset coil, and a method for manufacturing the same.

### BACKGROUND

Sensors based on magneto-resistance (MR) effects have been widely used. Typically, MR-based sensors include anisotropic magneto-resistance (AMR)-based sensors, giant magneto-resistance (GMR)-based sensors, and tunneling magneto-resistance (TMR)-based sensors.

In general, an electrical resistance (i.e., magneto-resistance) of a MR-based sensor changes with a change of a magnetic field, such as a change in magnitude or direction thereof. A magnetic field sensor of this kind typically has a layer of soft magnetic material of iron, cobalt, nickel, or permalloy such as cobalt-iron-boron alloy or nickel-iron alloy. A change in magnitude or direction of a magnetic field would change a magnetization direction of the soft magnetic material, thereby changing a resistance thereof.

To achieve an accurate measurement of the magnetic field, the soft magnetic layer needs to be re-magnetized before the magnetic field sensor is used for the measurement. A common method for re-magnetizing the soft magnetic layer is passing a large current through a wire adjacent to a basic sensing unit of the magnetic field sensor. The large current would produce a strong magnetic field, and all magnetic domains of the basic sensing unit would be arranged to align with a magnetic easy axis. The magnetic easy axis depends on anisotropy of the basic sensing unit of the magnetic field sensor. Depending on the direction of the current in the wire, the magnetic domains may be arranged along one of the two opposite directions parallel with the magnetic easy axis. Generally, such an operation is called a function of “set” or “reset”. In addition to initializing the magnetization of the soft magnetic layer, the set-reset function may also help restoring the magnetization of the soft magnetic layer. That is, if the magnetic field sensor is disturbed momentarily by an external magnetic field which is rather strong, even after the disturbing magnetic field is removed, the magnetic domains of the soft magnetic layer may not be able to restore to their initial states. This could result in a subsequent measurement error. With the set-reset function, the magnetic domains of the soft magnetic layer can be restored.

FIG. 1 shows a structural diagram of a conventional magnetic field sensor 100. The magnetic field sensor 100 includes a first power supply terminal 131, a second power supply terminal 132, a first output terminal 133, a second output terminal 134, a first sensing unit 111, a second sensing unit 112, a third sensing unit 113, a fourth sensing unit 114, and a reset coil 120 disposed adjacent to (e.g., above or below) the sensing units 111, 112, 113 and 114. The magnetic field sensor 100 may operate in a set-reset mode. In other words, the magnetic field sensor 100 has a set-reset function.

Each of the sensing units 111-114 has a magnetic easy axis, as well as a magneto-sensitive axis that is perpendicular to the magnetic easy axis. In FIG. 1, the magnetic easy axes of the sensing units 111-114 are in parallel, and the magneto-sensitive axes of the sensing units 111-114 are also in parallel. For the convenience of description, an x-axis and a y-axis perpendicular to the x-axis are defined in FIG. 1. Specifically, the x-axis is defined to be parallel with the magnetic easy axis of each of the sensing units 111-114, and the y-axis is defined to be parallel with the magneto-sensitive axis of each of the sensing units 111-114.

When the magnetic field sensor 100 operates in the set-reset mode, a strong current flows through the reset coil 120 to generate a magnetic field in a plane where the sensing units 111, 112, 113 and 114 are located. The magnetic field generated by the reset coil 120 sets or resets the sensing units 111, 112, 113 and 114 such that magnetic domains of the each of sensing units 111, 112, 113 and 114 are aligned with, or return to, the magnetic easy axis of the respective sensing unit.

The sensing units in FIG. 1 constitute a Wheatstone bridge structure. FIG. 2 shows a circuit diagram of the Wheatstone bridge structure in FIG. 1. The first power supply terminal 131 may be a power supply voltage terminal, and the second power supply terminal 132 may be a ground terminal. A magnetic field having a component parallel with the magneto-sensitive axes (i.e., having a y-axis component, or y-component) may change the magneto-resistance(s) of one or more of the sensing units 111-114. The change of the magneto-resistance(s) may lead to a change of a voltage across the first output terminal 133 and the second output terminal 134, and by detecting the change of the voltage a value of the magnetic field may be detected.

A disadvantage of the magnetic field sensor 100 resides in a physical structure of the reset coil 120, which is a planner reset coil as shown in FIG. 1. Specifically, the reset coil 120 is disposed in, or made of, a single layer of metal. Being a planner reset coil, the reset coil 120 needs to occupy a larger area in order to generate a magnetic field that is strong enough to set or reset the sensing units.

Therefore, there is a need for an improved magnetic field sensor to overcome the disadvantage mentioned above and improve an area utilization of the reset coil.

### SUMMARY

This section is for the purpose of summarizing some aspects of the present disclosure and to briefly introduce some preferred embodiments. Simplifications or omissions in this section as well as in the abstract or the title of this description may be made to avoid obscuring the purpose of this section, the abstract and the title. Such simplifications or omissions are not intended to limit the scope of the present disclosure.

One object of the present disclosure is to provide an improved magnetic field sensor with a three-dimensional spiral reset coil surrounding a corresponding sensor unit. With a certain current passing through, the three-dimensional spiral reset coil is able to generate a stronger magnetic field as compared to a conventional planner reset coil.

Another object of the present disclosure is to provide a method for manufacturing the improved magnetic field sensor having at least one of the three-dimensional spiral reset coil.

According to one aspect of the present disclosure, the present disclosure provides a magnetic field sensor. The magnetic field sensor may include at least one sensing unit having a magnetic easy axis and a magneto-sensitive axis perpendicular to the magnetic easy axis. The magnetic field sensor may also include at least one spiral reset coil, each spiral reset coil spirally surrounding a corresponding sensing unit of the at least one sensing unit. Each spiral reset coil may include a first wire portion disposed on a first side of the corresponding sensing unit. Each spiral reset coil may also include a second wire portion disposed on a second side of the corresponding sensing unit, wherein the second side opposite the first side. Each spiral reset coil may further include a third wire portion coupling the first wire portion and the second wire portion and passing through a plane where the corresponding sensing unit is located.

According to one aspect of the present disclosure, the present disclosure provides a method for manufacturing a magnetic field sensor. The method may involve depositing a first conductive layer on a substrate. The method may also involve patterning the first conductive layer to form a second wire portion. The method may also involve depositing a first dielectric layer on the patterned first conductive layer. The method may also involve forming a plurality of sensing units on the first dielectric layer. The method may also involve depositing a second dielectric layer on the sensing units and an exposed portion of the first dielectric layer. The method may also involve etching the second dielectric layer and the first dielectric layer to form a plurality of through-holes. The method may also involve filling the through-holes to form the third wire portion in the through-holes and depositing a second conductive layer on the second dielectric layer. The method may also involve patterning the second conductive layer to form a first wire portion. Moreover, the first wire portion, the second wire portion and the third wire portion are coupled to form a plurality of spiral reset coils each spirally surrounding corresponding a corresponding sensing unit of the plurality of sensing units.

One of the features, benefits and advantages in the present disclosure is to provide techniques for providing a three-dimensional spiral reset coil spirally surrounding a corresponding sensing unit. Compared to a conventional planner reset coil, the three-dimensional spiral reset coil can generate a stronger magnetic field using a same current. Thus, an area utilization of the magnetic field sensor may be enhanced by employing one or more three-dimensional spiral reset coils that utilize the area more effectively.

Other objects, features, and advantages of the present disclosure will become apparent upon examining the following detailed description of an embodiment thereof, taken in conjunction with the attached drawings.

### BRIEF DESCRIPTION OF THE DRAWINGS

These and other features, aspects, and advantages of the present disclosure will become better understood with regard to the following description, appended claims, and accompanying drawings.

FIG. 1 is a structure diagram of a conventional magnetic field sensor.

FIG. 2 is a circuit diagram of a Wheatstone bridge of the magnetic field sensor shown in FIG. 1.

FIG. 3a is a structure diagram of a magnetic field sensor according to a first embodiment of the present disclosure.

FIG. 3b is a cross-sectional schematic view along a sectional line a-a in FIG. 3a.

FIG. 3c is a cross-sectional schematic view along a sectional line b-b in FIG. 3a.

FIG. 4 is a structure diagram of a magnetic field sensor according to a second embodiment of the present disclosure.

FIG. 5 is a flowchart of a process for manufacturing a magnetic field sensor according to one embodiment of the present disclosure.

FIGS. 6a-6f are step-by-step diagrams showing the magnetic field sensor during the manufacturing process of FIG. 5.

FIG. 7 is a structure diagram of a magnetic field sensor according to a third embodiment of the present disclosure.

### DETAILED DESCRIPTION OF THE PREFERRED EMBODIMENTS

The detailed description of the present disclosure is presented largely in terms of procedures, steps, logic blocks, processing, or other symbolic representations that directly or indirectly resemble the operations of devices or systems contemplated in the present disclosure. These descriptions and representations are typically used by those skilled in the art to most effectively convey the substance of their work to others skilled in the art.

Reference herein to “one embodiment” or “an embodiment” means that a particular feature, structure, or characteristic described in connection with the embodiment can be included in at least one embodiment of the present disclosure. The appearances of the phrase “in one embodiment” in various places in the specification are not necessarily all referring to the same embodiment, nor are separate or alternative embodiments mutually exclusive of other embodiments. Further, the order of blocks in process flowcharts or diagrams or the use of sequence numbers representing one or more embodiments of the present disclosure do not inherently indicate any particular order nor imply any limitations in the present disclosure.

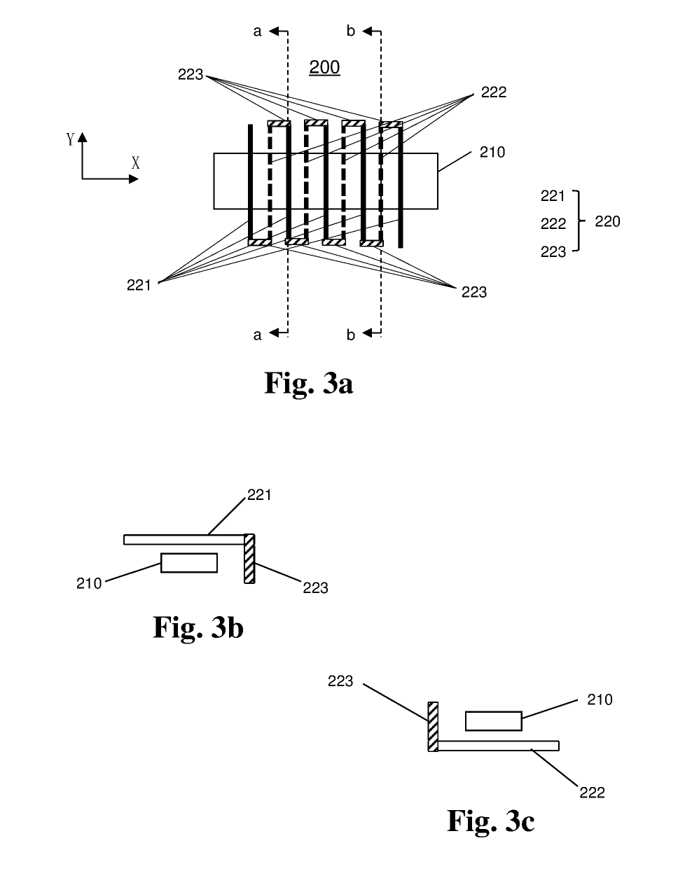

FIG. 3a is a structure diagram of a magnetic field sensor 200 according to a first embodiment of the present disclosure. FIG. 3b is a cross-sectional schematic view of the magnetic field sensor 200 along a sectional line a-a in FIG. 3a. Likewise, FIG. 3c is a cross-sectional schematic view of the magnetic field sensor 200 along a sectional line b-b in FIG. 3a. As shown in FIGS. 3a-3c, the magnetic field sensor 200 includes a sensing unit 210 and a three-dimensional spiral reset coil 220.

The sensing unit 210 has a magnetic easy axis, as well as a magneto-sensitive axis that is perpendicular to the magnetic easy axis. For the convenience of description, an x-axis and a y-axis perpendicular to the x-axis are defined in FIG. 3a. Specifically, the x-axis is defined to be parallel with the magnetic easy axis of the sensing unit 210, and the y-axis is defined to be parallel with the magneto-sensitive axis of the sensing unit 210. The sensing unit 210 may be an AMR-based sensing unit, a GMR-based sensing unit, or a TMR-based sensing unit.

In one embodiment, the sensing unit 210 may include a longitudinal magneto-resistive bar extending along the magnetic easy axis. The sensing unit 210 may also include a plurality of electrically conductive stripes that are parallel with each other. Each conductive stripe may be disposed on the magneto-resistive bar and form a predetermined angle with the magneto-resistive bar. The magneto-resistive bar may be made of a soft magnetic material such as iron, cobalt, nickel, cobalt-iron-boron alloy or nickel-iron alloy. A layer where the magneto-resistive bar is located is called a soft magnetic layer or a magneto-resistive layer. The conductive stripes may be made of an electrically conductive material such as titanium (Ti), copper (Cu), and the like.

With reference to FIG. 3a, FIG. 3b and FIG. 3c, the spiral reset coil 220 spirally surrounds the corresponding sensing unit 210. The spiral reset coil 220 includes a first wire portion 221 disposed above the corresponding sensing unit 210, a second wire portion 222 disposed below the corresponding sensing unit 210, and a third wire portion 223 coupling the first wire portion 221 and the second wire portion 222 and passing through a plane where the corresponding sensing unit 210 is located. The first wire portion 221 is formed by patterning a conductive layer disposed above the sensing unit 210, and the second wire portion 220 is formed by patterning a conductive layer disposed below the sensing unit 210. Namely, the spiral reset coil 220 is formed by at least two conductive layers and is a three-dimensional spiral reset coil.

The magnetic field sensor 200 further includes a first dielectric layer (not shown in FIGS. 3a-3c) disposed between the sensing unit 210 and the second wire portion 222 of the spiral reset coil 220. In addition, the magnetic field sensor 200 also includes a second dielectric layer (not shown in FIGS. 3a-3c) disposed between the sensing unit 210 and the first wire portion 221 of the spiral reset coil 220.

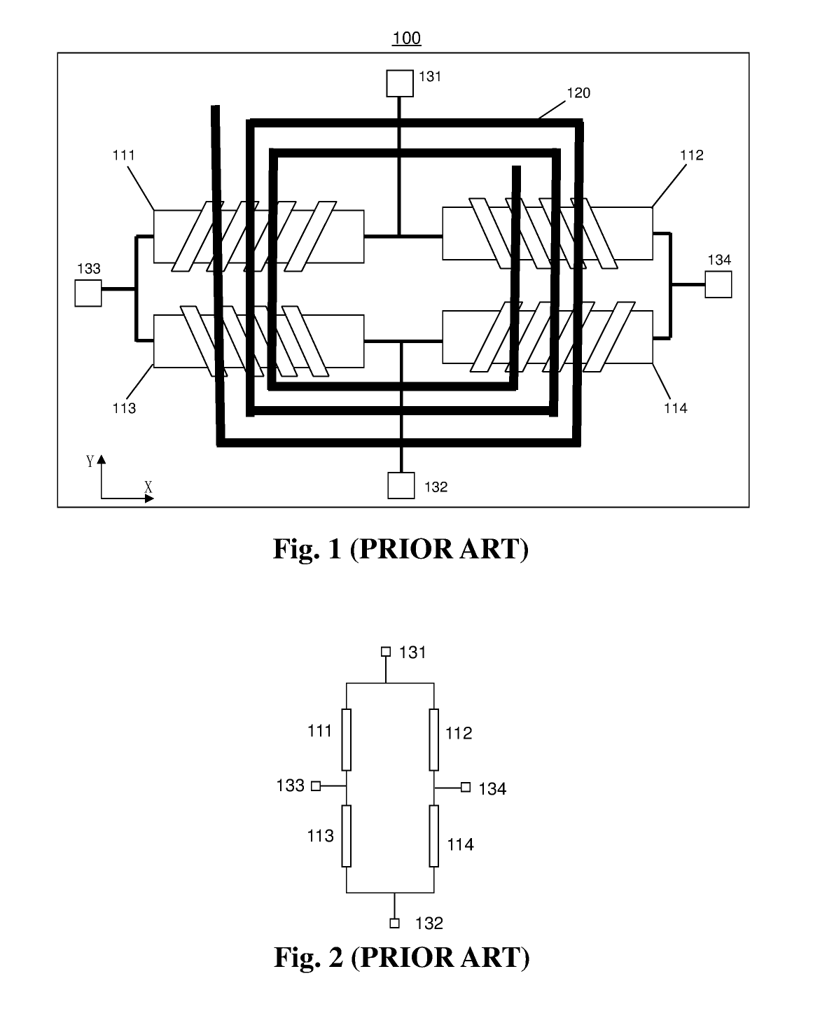

The magnetic field sensor 200 may operate in a set-reset mode. When the magnetic field sensor 200 operates in the set-reset mode, a current may pass through the spiral reset coil 220 to produce a magnetic field in a plane where the sensing unit 210 is located. The magnetic field may be parallel with the magnetic easy axis of the sensing unit 210, which may set or reset the corresponding sensing unit 210 such that magnetic domains of the sensing unit 210 are aligned with, or return to, the magnetic easy axis. Compared to the planner set coil of FIG. 1, the three-dimensional spiral reset coil 220 of FIG. 2 may generate a stronger magnetic field with the same current. In other words, the magnetic field sensor 200 may enable a more effective area utilization of a substrate on which a plurality of magnetic field sensors 200 may be manufactured.

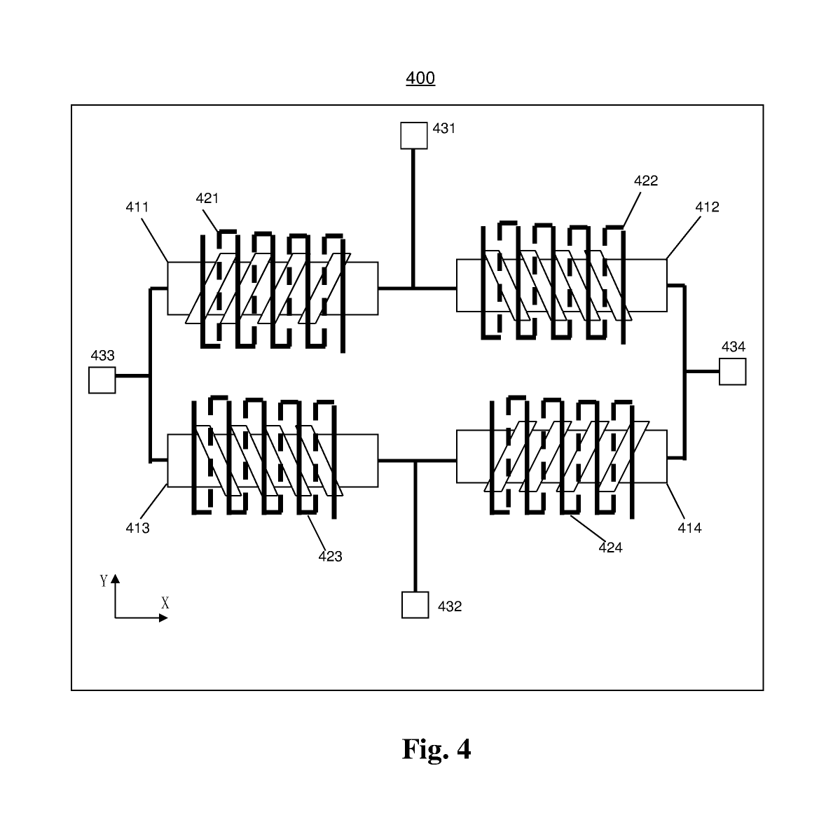

FIG. 4 shows a diagram of a magnetic field sensor according to a second embodiment 400 of the present disclosure. As shown in FIG. 4, the magnetic field sensor 400 includes a first power supply terminal 431, a second power supply terminal 432, a first output terminal 433, a second output terminal 434, a first sensing unit 411, a second sensing unit 412, a third sensing unit 413, a fourth sensing unit 414, a first spiral reset coil 421, a second spiral reset coil 422, a third spiral reset coil 423, and a fourth spiral reset coil 424. In particular, the first spiral reset coil 421, the second spiral reset coil 422, the third spiral reset coil 423 and the fourth spiral reset coil 424 correspond to the first sensing unit 411, the second sensing unit 412, the third sensing unit 413 and the fourth sensing unit 414, respectively.

Furthermore, the first power supply terminal 431 is coupled to a first end of the first sensing unit 411 and a first end of the second sensing unit 412; the second power supply terminal 432 is coupled to a second end of the third sensing unit 413 and a second end of the fourth sensing unit 414; the first output terminal 433 is coupled to a second end of the first sensing unit 411 and a first end of the third sensing unit 413; and the second output terminal 434 is coupled to a second end of the second sensing unit 412 and a first end of the fourth sensing unit 414.

Each sensing unit of magnetic field sensor 400 has a magnetic easy axis and a magneto-sensitive axis perpendicular to the magnetic easy axis. Similar to magnetic field sensor 200 of FIG. 3a, an x-axis and a y-axis perpendicular to the x-axis may be defined, with the magnetic easy axes of the sensing units parallel with the x-axis, and the magneto-sensitive axes of the sensing units parallel with the y-axis. The type, structure, working principle and manufacturing process of each sensing unit in FIG. 4 may be referred to the sensor unit 210 in FIG. 3a, and will not be repeated here.

Similar to magnetic field sensor 200 of FIG. 3a, the magnetic field sensor 400 may also operate in a set-reset mode.

When the magnetic field sensor 400 operates in the set-reset mode, each of the spiral reset coils 421, 422, 423 and 424 may pass a current to produce a respective magnetic field. The respective magnetic field may set or reset the corresponding sensing unit 411, 412, 413 or 414 such that the magnetic domains of the corresponding sensing unit are aligned with, or return to, the magnetic easy axis of the corresponding sensing unit. In one preferred embodiment, the spiral reset coils 421, 422, 423, 424 may be connected in a head-to-tail fashion such that only two connection terminals are needed for the spiral reset coils 421, 422, 423 and 424.

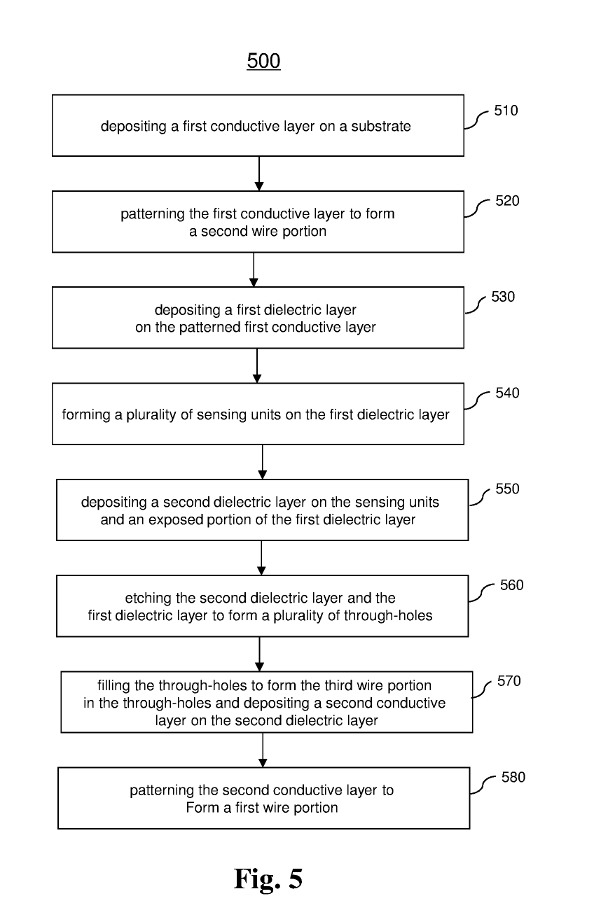

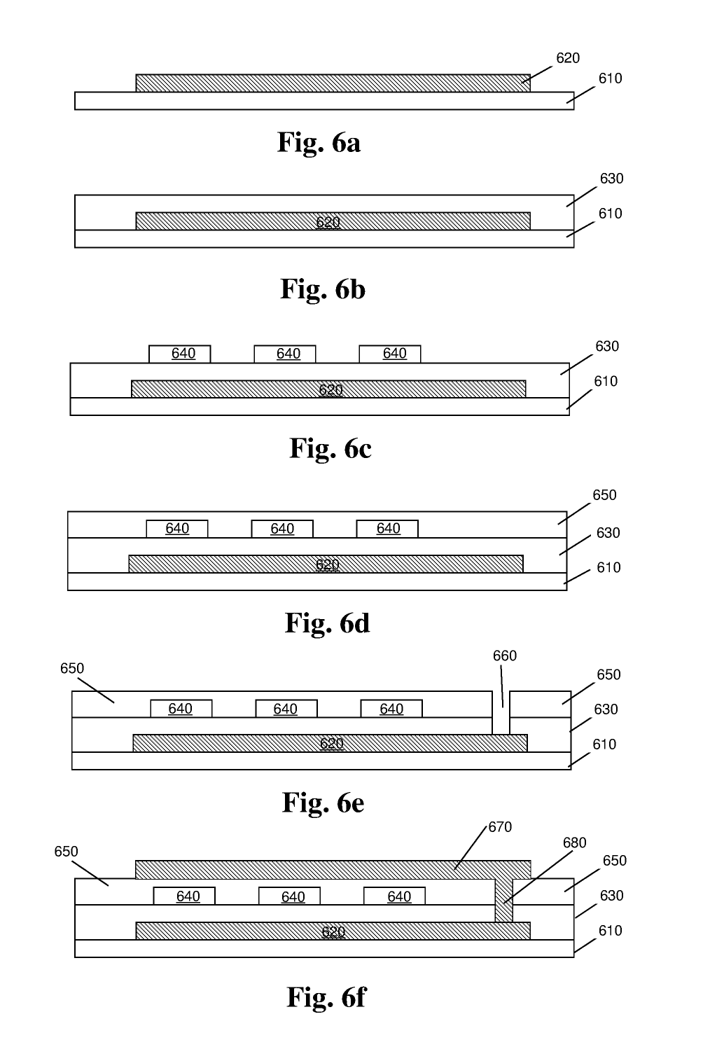

According to another aspect of the present disclosure, an example process for manufacturing a magnetic field sensor, such as one shown in FIG. 3a or FIG. 4, is provided. As shown in FIG. 5, the process 500 for manufacturing a magnetic field sensor may include one or more operations, actions, or functions as illustrated by one or more blocks 510, 520, 530, 540, 550, 560, 570 and 580. In addition, FIGS. 6a-6f provide step-by-step diagrams showing the magnetic field sensor during the manufacturing process 500 of FIG. 5. Process 500 may begin at block 510.

At 510, a first conductive layer 620 may be deposited on a substrate 610, as shown in FIG. 6a. Process 500 may proceed from 510 to 520.

At 520, the first conductive layer 620 may be patterned to form a second wire portion, such as the second wire portion 222 of FIGS. 3a and 3c. Process 500 may proceed from 520 to 530.

At 530, a first dielectric layer 630 may be deposited on the patterned first conductive layer 620, as shown in FIG. 6b. Process 500 may proceed from 530 to 540.

At 540, a plurality of sensing units 640 may be formed on the first dielectric layer 630, as shown in FIG. 6c. Process 500 may proceed from 540 to 550.

At 550, a second dielectric layer 650 may be formed or otherwise deposited on the sensing units 640 and an exposed portion of the first dielectric layer 630, as shown in FIG. 6d. Process 500 may proceed from 550 to 560.

At 560, the second dielectric layer 650 and the first dielectric layer 630 may be etched to form a plurality of through-holes, such as through-hole 660 as shown in FIG. 6e. Process 500 may proceed from 560 to 570.

At 570, a second conductive layer 670 may be deposited on the second dielectric layer 650 after the through-holes are formed, and part of the second conductive layer 670 may fill the through-holes to form a third wire portion 680, such as the third wire portion 223 of FIGS. 3a-3c, as shown in FIG. 6f. In some embodiments, a separate through-hole filling process step may be used to fill the through-holes with an electrically conductive material and form the third wire portion 680. The second conductive layer 670 that is subsequently deposited on the second dielectric layer 650 may also reach the through-holes that have been filled in the separate through-hole filling process step, thereby electrically coupled to the first wire portion via the third wire portion. Process 500 may proceed from 570 to 580.

At 580, the second conductive layer 670 may be patterned to form a first wire portion, such as the first wire portion 221 of FIGS. 3a and 3b.

As such, the first wire portion, the second wire portion and the third wire portion of process 500 may be coupled to form a plurality of spiral reset coils which spirally surround corresponding sensing units, such as sensing units 640 of FIG. 6.

In a preferred embodiment, the first wire portion of a spiral reset coil may be formed by a plurality of conductive layers. Similarly, the second wire portion of the spiral reset coil may also be formed by a plurality of conductive layers. Consequently, the spiral reset coil may constitute more turns within a same area, and thus an even stronger set-reset magnetic field may be resulted. In other words, by forming the first and second wire portions using a plurality of conductive layers, a strong spiral reset coil may be achieved in a limited area.

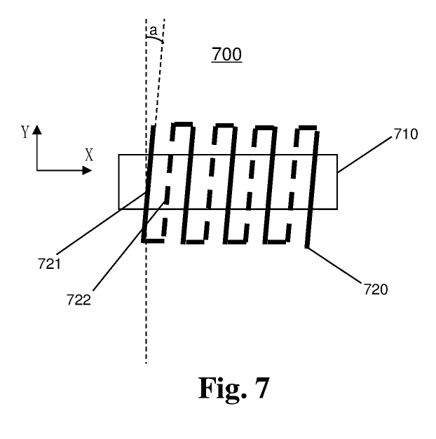

FIG. 7 is a structure diagram of a magnetic field sensor 700 according to a third embodiment of the present disclosure. The magnetic field sensor 700 shown in FIG. 7 is similar to the magnetic field sensor 200 of FIG. 3a. For example, the magnetic field sensor 700 also includes a sensing unit 710 and a spiral reset coil 720, which also spirally surrounds the sensing unit 710. Furthermore, the spiral reset coil also includes a first wire portion 721 disposed above the sensing unit 710, a second wire portion 722 disposed below the sensing unit 710, and a third wire portion coupling the first wire portion 721 and the second wire portion 722 and passing through a plane where the sensing unit 710 is located.

The difference between the magnetic field sensor 700 of FIG. 7 and the magnetic field sensor 200 of FIG. 3a lies in that, the first wire portion 721 and the second wire portion 722 of the spiral reset coil 720 in FIG. 7 is at a predetermined angle a with respect to the magneto-sensitive axis of the sensing unit 710. The predetermined angle a may be greater than 0 degrees and less than 45 degrees. Preferably, the predetermined angle a may be greater than 4 degrees and less than 15 degrees. Consequently, when a current passes through the spiral reset coil 720, the magnetic field generated by the spiral reset coil 720 may have an x-axis component (i.e., a component parallel with the magnetic easy axis of sensing unit 710) and a y-axis component (i.e., a component parallel with the magneto-sensitive axis of sensing unit 710). It is to be noted that, if the predetermined angle a is 0 degrees, the magnetic field sensor 700 will be identical to the magnetic field sensor 200 shown in FIG. 3a.

The magnetic field sensor 700 may operate in a set-reset mode and a self-test mode. When the magnetic field sensor 700 operates in the set-reset mode, a first current may flow through the spiral reset coil 720, and the x-axis component (or “x-component” in short) of a first magnetic field generated by the spiral reset coil 720 may set or reset the sensing unit 710. When the magnetic field sensor 700 operates in the self-test mode, a second current may flow through the spiral reset coil 720 and generate a second magnetic field. The second magnetic field may have a known or predetermined value, particularly a known value of its y-axis component (or “y-component” in short). A measurement reading of the magnetic field sensor 720 may then be compared with the known y-component to calibrate sensitivity, error and/or other parameters of the magnetic field sensor 700, thereby resulting in a self-test of the magnetic field sensor 700. In some embodiments, the second current may be less than the first current.

Accordingly, the magnetic field sensor 700 may realize a set-reset function as well as a self-test function by one spiral reset coil 720.

The present disclosure has been described in sufficient details with a certain degree of particularity. It is understood to those skilled in the art that the present disclosure of embodiments has been made by way of examples only and that numerous changes in the arrangement and combination of parts may be resorted without departing from the spirit and scope of the present disclosure as claimed. Accordingly, the scope of the present disclosure is defined by the appended claims rather than the foregoing description of embodiments.

What is claimed is:

1. A magnetic field sensor, comprising:
at least one sensing unit having a magnetic easy axis and a magneto-sensitive axis perpendicular to the magnetic easy axis; and
at least one spiral reset coil each spirally surrounding a corresponding sensing unit of the at least one sensing unit and comprising:
a first wire portion disposed on a first side of the corresponding sensing unit;
a second wire portion disposed on a second side of the corresponding sensing unit, the second side opposite the first side; and
a third wire portion coupling the first wire portion and the second wire portion and passing through a plane where the corresponding sensing unit is located.

2. The magnetic field sensor of claim 1, wherein:
the magnetic field sensor has a set-reset mode,
when the magnetic field sensor is in the set-reset mode, a current passing through the at least one spiral reset coil produces a magnetic field in a plane where the corresponding sensing unit is located, the magnetic field parallel with the magnetic easy axis of the corresponding sensing unit and setting or resetting the corresponding sensing unit such that magnetic domains of the corresponding sensing unit are aligned with the magnetic easy axis.

3. The magnetic field sensor of claim 1, wherein:
the at least one sensing unit comprises a plurality of sensing units, the magnetic easy axes of the plurality of sensing units parallel with each other, and
the at least one spiral reset coil comprises a plurality of spiral reset coils each corresponding to a respective one of the plurality of sensing units.

4. The magnetic field sensor of claim 3, further comprising:
a first power supply terminal;
a second power supply terminal;
a first output terminal; and
a second output terminal,
wherein:
the plurality of sensing units comprises four sensing units respectively denoted as a first sensing unit, a second sensing unit, a third sensing unit and a fourth sensing unit,
the plurality of spiral reset coils comprises four spiral reset coils respectively denoted as a first spiral reset coil, a second spiral reset coil, a third spiral reset coil and a fourth spiral reset coil, the first, second, third and fourth coils corresponding to the first, second, third and fourth sensing units, respectively,
the first power supply terminal is coupled to a first end of the first sensing unit and a first end of the second sensing unit,
the second power supply terminal is coupled to a second end of the third sensing unit and a second end of the fourth sensing unit,
the first output terminal is coupled to a second end of the first sensing unit and a first end of the third sensing unit, and
the second output terminal is coupled to a second end of the second sensing unit and a first end of the fourth sensing unit.

5. The magnetic field sensor of claim 1, wherein the at least one sensing unit comprises an anisotropic magneto-resistance-based sensing unit, a giant magneto-resistance-based sensing unit, or a tunneling magneto-resistance-based sensing unit.

6. The magnetic field sensor of claim 1, further comprising:
a first dielectric layer disposed between the corresponding sensing unit and the second wire portion of the spiral reset coil; and
a second dielectric layer disposed between the sensing unit and the first wire portion of the spiral reset coil.

7. The magnetic field sensor of claim 1, wherein the corresponding sensing unit comprises a longitudinal magneto-resistive bar and a plurality of conductive stripes disposed on the magneto-resistive bar, the longitudinal magneto-resistive bar extending along the magnetic easy axis, the plurality of conductive stripes parallel with each other and forming a predetermined angle with the longitudinal magneto-resistive bar.

8. The magnetic field sensor of claim 7, wherein the magneto-resistive bar comprises iron, cobalt, nickel, cobalt-iron-boron alloy or nickel-iron alloy.

9. The magnetic field sensor of claim 1, wherein the first wire portion comprises a plurality of conductive layers, and wherein the second wire portion comprises a plurality of conductive layers.

10. The magnetic field sensor of claim 1, wherein a predetermined angle is formed between an extension direction of the first or second wire portion and the magneto-sensitive axis of the corresponding sensing unit, and wherein the predetermined angle is greater than 0 degree and less than 45 degrees.

11. The magnetic field sensor of claim 10, wherein the predetermined angle is greater than 4 degrees and less than 15 degrees.

12. The magnetic field sensor of claim 10, wherein:
the magnetic field sensor has a set-reset mode and a self-test mode,
when the magnetic field sensor is in the set-reset mode, a first current passing through the at least one spiral reset coil produces a first magnetic field, and an x-component of the first magnetic field sets or resets the corresponding sensing unit,
when the magnetic field sensor is in the self-test mode, a second current passing through the spiral reset coil produces a second magnetic field having a known y-axis component, and a self-test is realized by comparing a measurement reading of the magnetic field sensor with the known y-axis component of the second magnetic field, and
the second current is less than the first current.

13. A method for manufacturing a magnetic field sensor, comprising:
depositing a first conductive layer on a substrate;
patterning the first conductive layer into a patterned first conductive layer to form a second wire portion;
depositing a first dielectric layer on the patterned first conductive layer;
forming a plurality of sensing units on the first dielectric layer;
depositing a second dielectric layer on the sensing units and an exposed portion of the first dielectric layer;
etching the second dielectric layer and the first dielectric layer to form a plurality of through-holes;
filling the through-holes to form the third wire portion in the through-holes and depositing a second conductive layer on the second dielectric layer; and
patterning the second conductive layer to form a first wire portion,
wherein the first wire portion, the second wire portion and the third wire portion are coupled to form a plurality of spiral reset coils each spirally surrounding a corresponding sensing unit of the plurality of sensing units.
